(19) United States
(12) Patent Application Publication
(10) Pub. No.: US 2003/0085055 A1
(43) Pub. Date: May 8, 2003

(54) Substrate design and process for reducing electromagnetic emission

(76) Inventors: Harry G. Skinner, Beaverton, OR (US); Bryce D. Horine, Beaverton, OR (US)

Correspondence Address: Seth Z. Kalson, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/991,622

(22) Filed: Nov. 5, 2001

(51) Int. Cl. H05K 7/06

(52) U.S. Cl. 174/255; 174/260; 361/780

(57) ABSTRACT

In one embodiment, reducing electromagnetic radiation from sources within a substrate, such as a substrate for supporting an integrated circuit die, where the substrate comprises power layers, ground layers, and ground rings surrounding all or a portion of the power layers, where the ground layers and the ground rings are extended at least to the edges of the substrate so that conductive plates may be in electrical contact with the ground layers and the ground rings so as to define an enclosure to substantially contain electromagnetic radiation from sources within the defined enclosure.

### FIELD

Embodiments of the present invention relate to reducing unwanted electromagnetic radiation from electronic devices or integrated circuit dice, and more particularly, to structures or substrates supporting electronic devices or integrated circuit dice and the reduction of electromagnetic radiation.

### BACKGROUND

Electronic systems often comprise several integrated circuit devices mounted on a printed circuit board (PCB), with electrical connections provided for power delivery, grounding, and communication of signals between the several mounted devices. These electrical connections, or traces, and the power delivery system, may physically reside on different layers within a multi-layer PCB. Similarly, an individual integrated circuit die, such as a microprocessor, comprises signal traces for communicating signals among different functional units and power delivery busses for powering the different functional units, where these traces and power delivery busses physically reside on various layers in a multi-layer substrate.

The traces and power delivery busses on a substrate, whether a PCB or a substrate for an integrated circuit die, may be modeled as transmission lines for sufficiently low frequencies. However, as frequencies become higher, traces and power delivery busses will start to act like antennas, radiating unwanted electromagnetic signals. For computer systems, microprocessors are often a major source of electromagnetic radiation (emission). Electromagnetic resonances (standing waves) associated with the microprocessor power bus have been identified as a major contributor to unwanted electromagnetic radiation.

Below microprocessor frequencies of 8 GHz, electromagnetic radiation due to resonances may be significantly reduced by the use of multi-layer substrates and the proper placement of vias. One such method is taught in U.S. Pat. No. 6,191,475, “Substrate for Reducing Electromagnetic Interference and Enclosure,” by Skinner et al., and is briefly described in connection with FIG. 1.

FIG. 1 is a simplified edge view (vertical slice) of a multi-layer substrate, comprising ground layers 102 and power (V_{CC}) layers (planes) 104. Ground rings 106 surround all or most of power layers 104. Vias 108 connect ground rings 106 to ground layers (planes) 102. For simplicity, only two vias are shown in FIG. 1, but in practice a plurality of vias connect ground rings 106 to ground layers 102, where these vias are placed at different positions along ground rings 106. In some cases, the distances between adjacent vias may follow a random pattern to better contain electromagnetic radiation due to electromagnetic resonance. To substantially contain electromagnetic radiation, the nominal distances separating adjacent vias should be no more than 1/20 of the operating wavelength. For frequencies above 8 GHz, this spacing requirement for vias is difficult and costly to implement.

### BRIEF DESCRIPTION OF THE DRAWINGS

FIG. 1 is a prior art substrate having vias for containing electromagnetic radiation from sources within the substrate.

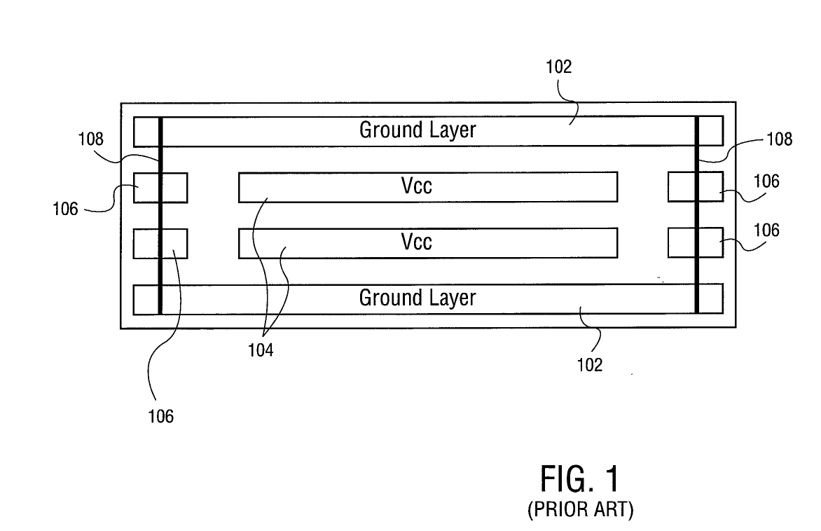

FIG. 2 is an embodiment according to the present invention.

### DESCRIPTION OF EMBODIMENTS

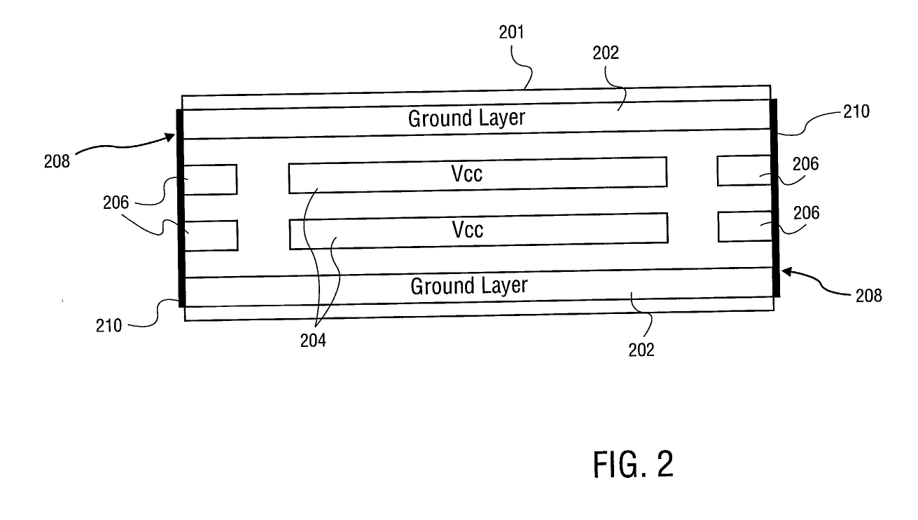

FIG. 2 provides an edge view (vertical slice) of an embodiment of the present invention, where 201 may be a PCB supporting a plurality of integrated circuit devices, or a substrate for an integrated circuit die. For simplicity, it will be understood that a PCB or a substrate for an integrated circuit die will be referred to as simply a substrate, so that 201 will be referred to as simply a substrate.

As discussed in the background section, ground rings 206 surround all or part of power layers 204. However, ground rings 106 are now extended to edges 208, or just past edges 208, of substrate 201. Also, ground layers (planes) 202 are also extended to edges 208, or just past edges 208, of substrate 201. Ground layers 202 and ground rings 206 are extended so that conductive plates 210 are formed adjacent to edges 208 so as to be in electrical contact with ground rings 206 and ground layers 202. As a result, the combination of ground layers 202 and plates 210 define an enclosure to effectively contain electromagnetic radiation from sources within the enclosure, e.g., an integrated circuit die within substrate 201 or electronic devices embedded within substrate 201.

It is expected that embodiment 201 will effectively prevent unwanted electromagnetic radiation from sources within the defined enclosure for frequencies much higher than 8 GHz. In one embodiment, plates 210 are continuous in the sense that plates 210 contain no apertures (openings). If apertures are present in plates 210, then electromagnetic radiation may still effectively be contained provided the apertures are small enough, e.g., have spatial dimensions less than 1/20 of a wavelength of the operating frequency of the enclosed sources. There may, however, be one or more ports (openings) within ground layers 202 or plates 210 for connecting power lines, busses, or transmission lines for communicating with other devices.

Furthermore, if substrate 201 is a PCB, then at least one of ground layers 202 will have openings for the purpose of mounting one or more electronic packages, and for connecting the pins to various ground and power layers, as well as other traces or transmission lines (not shown) for communicating with other devices. However, unwanted electromagnetic radiation may still be greatly diminished provided the die packages themselves do not radiate unwanted electromagnetic radiation.

What is claimed is:

1. A substrate having edges, the substrate comprising:
at least one ground layer;
at least one power layer; and
at least one conductive plate adjacent to the edges and in electrical contact with the at least one ground layer.

2. The substrate as set forth in claim 1, wherein the at least one conductive plate has no apertures.

3. The substrate as set forth in claim 2, wherein the substrate supports an integrated circuit die.

4. The substrate as set forth in claim 2, wherein the substrate is a printed circuit board.

5. The substrate as set forth in claim 1, wherein the at least one conductive plate, the at least one ground layer, and the at least one power layer in combination define an enclosure to substantially contain electromagnetic radiation from a source within the defined enclosure.

6. The substrate as set forth in claim 5, wherein the substrate supports an integrated circuit die.

7. The substrate as set forth in claim 5, wherein the substrate is a printed circuit board

8. The substrate as set forth in claim 1, wherein the substrate supports an integrated circuit die.

9. The substrate as set forth in claim 1, wherein the substrate is a printed circuit board.

10. The substrate as set forth in claim 1, further comprising:
at least one ground ring in substantially a same layer as the at least one power layer and in electrical contact with the at least one conductive plate.

11. The substrate as set forth in claim 10, wherein the at least one conductive plate has no apertures.

12. The substrate as set forth in claim 11, wherein the substrate supports an integrated circuit die.

12. The substrate as set forth in claim 11, wherein the substrate is a printed circuit board.

13. The substrate as set forth in claim 10, wherein the at least one conductive plate, the at least one ground layer, and the at least one power layer in combination define an enclosure to substantially contain electromagnetic radiation from a source within the defined enclosure.

14. A method to substantially contain electromagnetic radiation from sources within a substrate, the substrate having edges, the method comprising:
forming at least one ground layer to extend to at least the edges;
forming at least one power layer; and
forming at least one conductive plate adjacent to the edges and in electrical contact with the at least one ground layer.

15. The method as set forth in claim 14, wherein the at least one conductive plate has no apertures.

16. The method as set forth in claim 15, wherein the substrate supports an integrated circuit die.

17. The method as set forth in claim 15, wherein the substrate is a printed circuit board.

18. The method as set forth in claim 14, wherein the at least one conductive plate, the at least one ground layer, and the at least one power layer in combination define an enclosure to substantially contain electromagnetic radiation from a source within the defined enclosure.

18. The method as set forth in claim 18, wherein the substrate supports an integrated circuit die.

19. The method as set forth in claim 18, wherein the substrate is a printed circuit board

20. The method as set forth in claim 14, wherein the substrate supports an integrated circuit die.

21. The method as set forth in claim 14, wherein the substrate is a printed circuit board.

22. The method as set forth in claim 14, further comprising:
forming at least one ground ring in correspondence with the at least one power layer so that each ground ring surrounds at least a portion of a corresponding power layer and lies in a same layer as the corresponding power layer; and
extending the at least one ground ring to at least the edges so as to be in electrical contact with the at least one conductive plate.

23. The method as set forth in claim 22, wherein the at least one conductive plate has no apertures.

24. The method as set forth in claim 23, wherein the substrate supports an integrated circuit die.

25. The method as set forth in claim 23, wherein the substrate is a printed circuit board.

26. The method as set forth in claim 22, wherein the at least one conductive plate, the at least one ground layer, and the at least one power layer in combination define an enclosure to substantially contain electromagnetic radiation from a source within the defined enclosure.

27. An apparatus comprising:
an integrated circuit die;
a substrate to support the integrated circuit die, the substrate having edges;
at least one ground layer;
at least one power layer; and
at least one conductive plate adjacent to the edges and in electrical contact with the at least one ground layer.

28. The apparatus as set forth in claim 27, wherein the at least one conductive plate has no apertures.

29. The apparatus as set forth in claim 27, the integrated circuit die radiating electromagnetic energy, wherein the at least one conductive plate, the at least one ground layer, and the at least one power layer in combination define an enclosure to substantially contain the electromagnetic energy.

30. The apparatus as set forth in claim 27, further comprising:
at least one ground ring in substantially a same layer as the at least one power layer and in electrical contact with the at least one conductive plate.
